(19) United States
(12) Patent Application Publication
(10) Pub. No.: US 2010/0156498 A1
(43) Pub. Date: Jun. 24, 2010

(54) LEVEL SHIFTER

(75) Inventor: Vikram Pradeepkumar Bagepalli, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/338,423

(22) Filed: Dec. 18, 2008

(51) Int. Cl. H03L 5/00

(52) U.S. Cl. 327/333

(57) ABSTRACT

A level shifter with high performance, low power and reduced duty cycle distortion. The level shifter includes an input stage having a first circuit coupled to a second circuit. The first circuit includes a first pull up transistor receiving an input signal coupled to a first pull down transistor. The second circuit includes a second pull up transistor coupled to a second pull down transistor. An output of the input stage coupled to a first node in the first circuit. The level shifter further includes an inverter receiving the input signal. An output of the inverter and the second pull down transistor coupled to a second node. An output stage of the level shifter generates an output signal. The output stage includes a first transistor coupled to the first node and a second transistor coupled to the second node.

### TECHNICAL FIELD

Embodiments of the invention relate generally to integrated circuits and more particularly to a level shifter.

### BACKGROUND

A level shifter is used to couple different voltage domains of the integrated circuit. FIG. 1 illustrates a conventional level shifter 100. The level shifter 100 includes an input stage having cross coupled transistors 110 and 115, transistor 105 and transistor 120. Transistor 105 receives an input signal on the line 140. Bias voltage VDD is supplied to the input stage. An output of the input stage is taken from a common junction between a drain of transistor 115 and a source of transistor 120. The output of the input stage is connected to the inverters 130 and 135. The input signal is also connected to another inverter 125 that receives a bias voltage VDDIN. An output of the inverter 125 is connected to a gate of the transistor 120. An output of the level shifter 100 is generated on a line 145.

The conventional level shifter 100 requires two inverters 130 and 135 at the output for level shifting. As the number of logic levels (inverters 130 and 135) at the output increases, the level shifter 100 needs more number of transistors that results in an increased power consumption and leakage current. The conventional level shifter 100 needs a different outlook while reducing power consumption and maintaining duty cycle distortion.

### SUMMARY

This Summary is provided to comply with 37 C.F.R. § 1.73, requiring a summary of the invention briefly indicating the nature and substance of the invention. It is submitted with the understanding that it will not be used to interpret or limit the scope or meaning of the claims.

An exemplary embodiment provides a level shifter. The level shifter includes an input stage having a first circuit coupled to a second circuit. The first circuit includes a first pull up transistor that receives an input signal, coupled to a first pull down transistor. The second circuit includes a second pull up transistor coupled to a second pull down transistor. An output of the input stage is coupled to a first node in the first circuit. The level shifter further includes an inverter receiving the input signal. An output of the inverter and the second pull down transistor are coupled to a second node. An output stage of the level shifter generates an output signal. The output stage includes a first transistor coupled to the first node and a second transistor coupled to the second node.

Another exemplary embodiment provides a level shifter. The level shifter includes an input stage coupled to an input node. The input stage includes a first circuit coupled to a second circuit. The first circuit includes a first pull up transistor, a first pull down transistor and a first PMOS transistor sequentially coupled to each other. The first pull up transistor and the PMOS transistor are coupled to the input node. Also, an output of the input stage is coupled to a first node between the first pull up transistor and the first pull down transistor. The second circuit includes a second pull up transistor, a second pull down transistor and a second PMOS transistor sequentially coupled to each other. An output of the input stage is coupled to a first node in the first circuit. The level shifter further includes an inverter receiving the input signal. An output of the inverter and the second pull down transistor are coupled to a second node. An output stage of the level shifter, generating an output signal, includes a first transistor coupled to the first node and a second transistor coupled to the second node.

An exemplary embodiment provides a method for level shifting. An input signal is inverted in a level shifter using an input stage. The input stage includes a first circuit coupled to a second circuit. The first circuit includes a first pull up transistor receiving an input signal coupled to a first pull down transistor. The second circuit includes a second pull up transistor coupled to a second pull down transistor. Further, an output of the input stage is coupled to a first node in the first circuit, and an output of an inverter and the second pull down transistor is coupled to a second node. A first transistor of an output stage is driven using the first node, and a second transistor of the output stage is driven using the second node.

Other aspects and example embodiments are provided in the Drawings and the Detailed Description that follows.

### BRIEF DESCRIPTION OF THE VIEWS OF DRAWINGS

FIG. 1 illustrates a conventional level shifter;

FIG. 2A illustrates a fall path of a level shifter according to an embodiment;

FIG. 2B illustrates a rise path of the level shifter according to an embodiment;

FIG. 3 illustrates a level shifter according to another embodiment;

FIG. 4 is a flow diagram illustrating a method for level shifting according an embodiment; and

FIG. 5 is a table illustrating the power and duty cycle comparison between the conventional level shifter and the level shifter of FIG. 3.

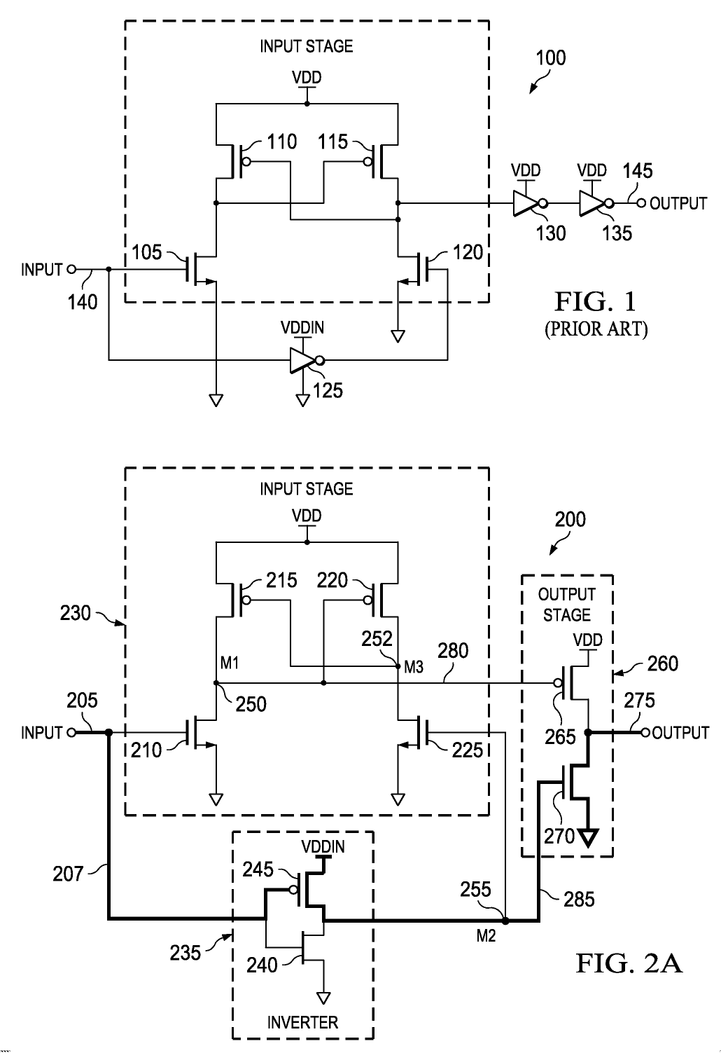

### DETAILED DESCRIPTION OF THE EMBODIMENTS

Embodiments described herein provide systems and method for level shifting. One embodiment provides a level shifter that achieves high performance, low power and reduced duty cycle distortion. An embodiment eliminates a need for inverter at the output stage of the level shifter. Another embodiment separates a rise path and a fall path of the level shifter. In various embodiments, a rise path of the level shifter includes a set of devices that may be active during initial stages of a low voltage to a high voltage transition at an input node of the level shifter which may result in a low voltage to a high voltage transition at an output node of the level shifter. In various embodiments, a fall path of the level shifter includes a set of devices that may be active during initial stages of a high voltage to low voltage transition at the input node of the level shifter which may result in a high voltage to a low voltage transition at an output node of the level shifter.

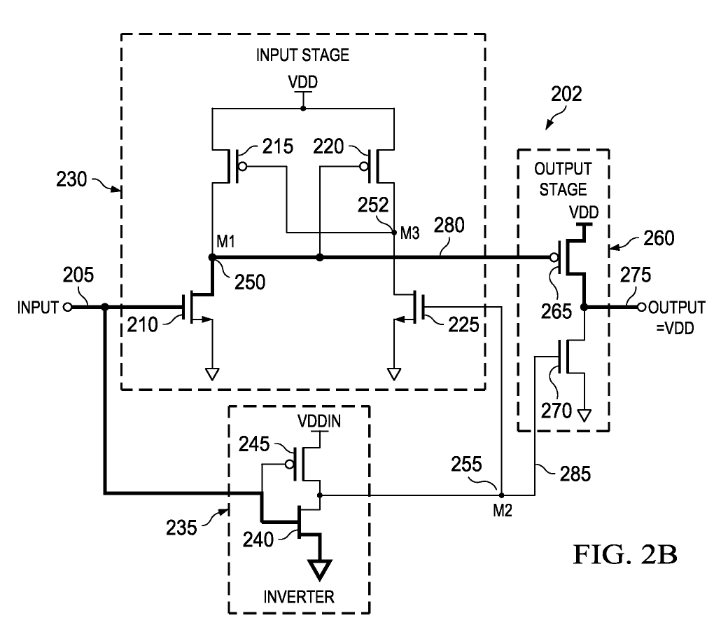

To explain the operation of the level shifter according to one embodiment, fall path is highlighted in FIG. 2A and rise path is highlighted in FIG. 2B. In FIG. 2A, the level shifter 200 includes an input stage 230, an inverter 235 and an output stage 260. The input stage 230 includes a first circuit connected to a second circuit. The first circuit includes a first pull up transistor 215 and a first pull down transistor 210. In this embodiment the first pull up transistor 215 includes a PMOS transistor and the first pull down transistor 210 includes an NMOS transistor. A drain of the transistor 215 is connected to a drain of the transistor 210. The second circuit includes a second pull up transistor 220 and a second pull down transistor 225. A drain of the transistor 220 is connected to a drain of the transistor 225. In this embodiment the second pull up transistor 220 includes a PMOS transistor and the second pull down transistor 225 includes an NMOS transistor. The input stage 230 receives a bias voltage VDD. Sources of the transistors 215 and 220 receive the VDD. Transistors 215 and 220 are cross coupled to each other. A gate of the transistor 215 is connected to the drain of the transistor 220. A gate of the transistor 220 is connected to the drain of the transistor 215. A gate of the transistor 210 receives an input signal on the line 205. A source of the transistor 210 is connected to the ground. A first node (node M1, 250 in FIG. 2A) includes a common junction between the drain of the transistor 215 and the drain of the transistor 210. An output of the input stage 230 is derived from the node M1, 250.

The inverter 235 includes a PMOS transistor 245 and an NMOS transistor 240. Gates of the transistors 240 and 245 are connected to each other and the gates receive the input signal. A source of the transistor 245 receives an external bias voltage VDDIN. A drain of the transistor 245 is connected to a drain of the transistor 240. A source of the transistor 240 is connected to the ground. An output of the inverter 235, taken from a common junction between drain of the transistor 245 and drain of the transistor 240, is connected to a second node (node M2, 255 in FIG. 2A). A gate of the transistor 225 of the input stage 230 is also connected to the node M2, 255.

The output stage 260 includes a PMOS transistor 265 and an NMOS transistor 270. A source of the transistor 265 receives bias voltage VDD. A gate of the transistor 265 is connected to the first node, node M1, 250. A drain of the transistor 265 is connected to a drain of the transistor 270. A gate of the transistor 270 is connected to the second node, node M2, 255. A source of the transistor 270 is connected to the ground. An output of the output stage 260 (output of the level shifter) is taken from a common junction between the drain of the transistor 265 and the drain of the transistor 270 on a line 275.

The fall path of the level shifter 200 includes transition from one state to the other of the transistor 245, the node M2 (255) and the transistor 270. When the input to the level shifter 200 is at low voltage, transistor 245 is turned ON. Due to this node M2, 255 transitions to a high voltage which is equal to the bias voltage VDDIN to the transistor 245. As a result, transistor 270 of the output stage (260) turns ON and pulls the output of the level shifter to a low voltage. Output of the level shifter 200 is the ground voltage since the transistor 270 is connected to the ground. Transistor 210 is inactive when the input is low voltage. Node M1, 250 and the node M3, 252 transitions to high voltage and low voltage respectively. The transistor 265 will remain turned OFF. Transistor 240 is inactivated due to the low voltage input at the gate.

In FIG. 2B, the rise path of the level shifter 202 includes transition from one state to the other of the transistor 210, node M1 (250), transistor 265 and transistor 240. When the input to the level shifter 202 is a high voltage, transistor 210 is turned ON. As a result, the node M1, 250 transitions from high voltage to a low voltage. This low voltage turns ON transistor 265 at the output stage 260 and pulls the output of the level shifter 202 to a high voltage. Also, transistor 220 at the input stage 230 is turned ON due to the low voltage at the node M1, 250. Transistor 215 turns ON when the transistor 220 is turned ON (since the transistors 215 and 220 are cross coupled) and the node M3, 252 is pulled high to ensure that node M1, 250 is at a stable low voltage (0V). Output of the level shifter 202 will be the bias voltage VDD to the output stage 260 in this case. The high voltage at the input turns ON the transistor 240 of the inverter 235. As a result node M2, 255 transitions from a low voltage to high voltage and in turn deactivates the transistor 270.

In one embodiment, a need for an inverter at the output stage of the level shifter is eliminated by using the transistor 265 and the transistor 270, which are driven by node M1, 250 and node M2, 255 respectively. Fall delay of the level shifter (causing duty cycle distortion) is significantly reduced by reducing a number of logic levels between the input stage and the output stage which in turn reduces the duty cycle distortion.

In one embodiment, the transistor 270 includes a high value transistor to match the output drive requirements in the absence of the inverter at the output stage. In one embodiment, total number of transistors is significantly reduced by eliminating a need for the inverter at the output stage. Reducing the number of transistors in turn reduces the leakage current and dynamic power requirements. Total area of implementation on a chip is also reduced using this embodiment.

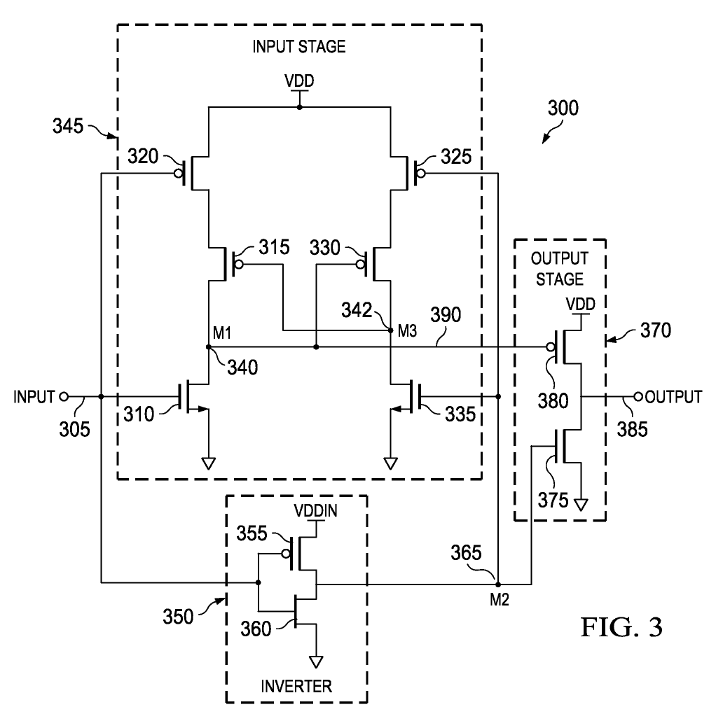

FIG. 3 illustrates a level shifter 300 according to another embodiment. The level shifter 300 includes an input stage 345, an inverter 350 and an output stage 370. The input stage 345 includes a first circuit connected to a second circuit. The first circuit includes a first pull up transistor 315 and a first pull down transistor 310 and a first PMOS transistor 320. A gate of the transistor 320 receives an input signal on the line 305. A drain of the transistor 320 is connected to a source of the transistor 315. A drain of the transistor 315 is connected to a drain of the transistor 310. In this embodiment the first pull up transistor 315 includes a PMOS transistor and the first pull down transistor 310 includes an NMOS transistor. The second circuit includes a second pull up transistor 330 and a second pull down transistor 335 and a second PMOS transistor 325. In this embodiment the second pull up transistor 330 includes a PMOS transistor and the second pull down transistor 325 includes an NMOS transistor. A source of the transistor 325 receives the bias voltage VDD. A drain of the transistor 325 is connected to a source of the transistor 330. A drain of the transistor 330 is connected to a drain of the transistor 335. The input stage receives a bias voltage VDD. Sources of the transistors 320 and 325 receive the VDD. Transistors 315 and 330 are cross coupled to each other. A gate of the transistor 315 is connected to the drain of the transistor 330. A gate of the transistor 330 is connected to the drain of the transistor 315. A gate of the transistor 310 receives an input signal on the line 305. A drain of the transistor 310 is connected to the ground. A first node (node M1, 340 in FIG. 3) includes a common junction between the drain of the transistor 315 and the source of the transistor 310. An output of the input stage 345 is derived from the node M1, 340.

The inverter 350 includes a PMOS transistor 355 and an NMOS transistor 360. Gates of the transistors 360 and 355 are connected to each other and receive the input signal. A source of the transistor 355 receives an external bias voltage VDDIN. A drain of the transistor 355 is connected to a drain of the transistor 360. A source of the transistor 360 is connected to the ground. An output of the inverter 350, taken from a common junction between drain of the transistor 355 and drain of the transistor 360, is connected to a second node (node M2, 365 in FIG. 3). A gate of the transistors 325 and 335 of the input stage 345 is also connected to the node M2, 365.

The output stage 370 includes a PMOS transistor 380 and an NMOS transistor 375. A source of the transistor 380 receives bias voltage VDD. A gate of the transistor 380 is connected to the first node, node M1, 340. A drain of the transistor 380 is connected to a source of the transistor 375. A gate of the transistor 375 is connected to the second node, node M2, 365. A source of the transistor 375 is connected to the ground. An output of the output stage (output of the level shifter) is taken from a common junction between the drain of the transistor 380 and the drain of the transistor 375.

A fall path of the level shifter 300 includes transition from one state to the other of the transistor 355, node M2, 365 and the transistor 375. When the input to the level shifter 300 is at low voltage, transistor 355 is turned ON. Due to this, node M2, 365 transitions to a high voltage which is equal to the bias voltage VDDIN to the transistor 355. As a result, transistor 375 of the output stage (370) turns ON and pulls the output of the level shifter 300 to a low voltage. Output of the level shifter 300 is the ground voltage since the transistor 375 is connected to the ground. Transistor 310 is inactive when the input is low voltage. Node M1, 340 and node M3, 342 transitions to high voltage and low voltage respectively. The transistor 380 will remain turned OFF. Transistor 360 is inactivated due to the low voltage input at the gate.

A rise path of the level shifter 300 includes transition from one state to the other of the transistor 310, node M1 (340), transistor 380 and transistor 360. When the input to the level shifter 300 is a high voltage, transistor 310 is turned ON. As a result, the node M1, 340 transitions from high voltage to a low voltage. This low voltage turns ON transistor 380 at the output stage 370 and pulls the output of the level shifter to a high voltage. The high voltage input also deactivates the transistor 320 blocking the bias voltage VDD. Further, node M3, 342 is pulled high to ensure that node M1, 340 is at a stable low voltage (0V). Output of the level shifter 300 will be the bias voltage VDD to the output stage 370 in this case. The high voltage at the input turns ON the transistor 360 of the inverter 350. As a result node M2, 365 transitions from a low voltage to high voltage and in turn deactivates the transistor 375.

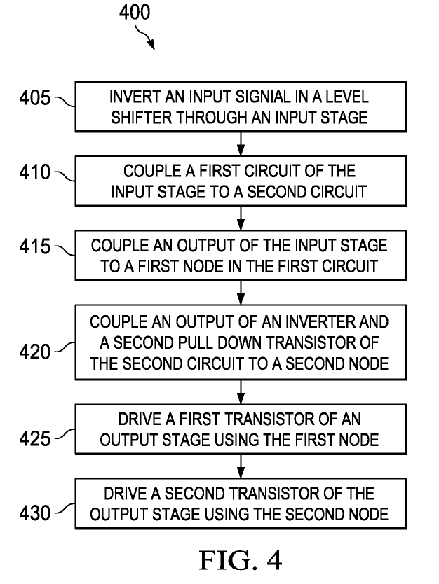

FIG. 4 is a flow diagram 400 illustrating a method for level shifting according an embodiment. At step 405, an input signal is inverted in a level shifter using an input stage, for example, the input stage 345. The input stage receives an external bias voltage. A first circuit in the input stage is coupled to a second circuit at step 410. The first circuit includes the transistors 310, 315 and 320. The second circuit includes the transistors 325, 330 and 335. At step 415, an output of the input stage is coupled to a first node in the first circuit, for example node M1, 340. At step 420, an output of an inverter, for example the inverter 350, and a second pull down transistor of the second circuit, for example the transistor 335, are coupled to a second node, for example node M2 (365). At step 425, a first transistor of an output stage, for example transistor 380 is driven by the first node while level shifting during a rise path of the level shifter. At step 430, a second transistor of the output stage, for example transistor 375 is driven by the second node, for example node M2 (365) during a fall path of the level shifter. Steps 425 and 430 separate the rise path and fall path of the level shifter. Steps 425 and 430 also eliminate the need for an inverter at the output stage of the level shifter.

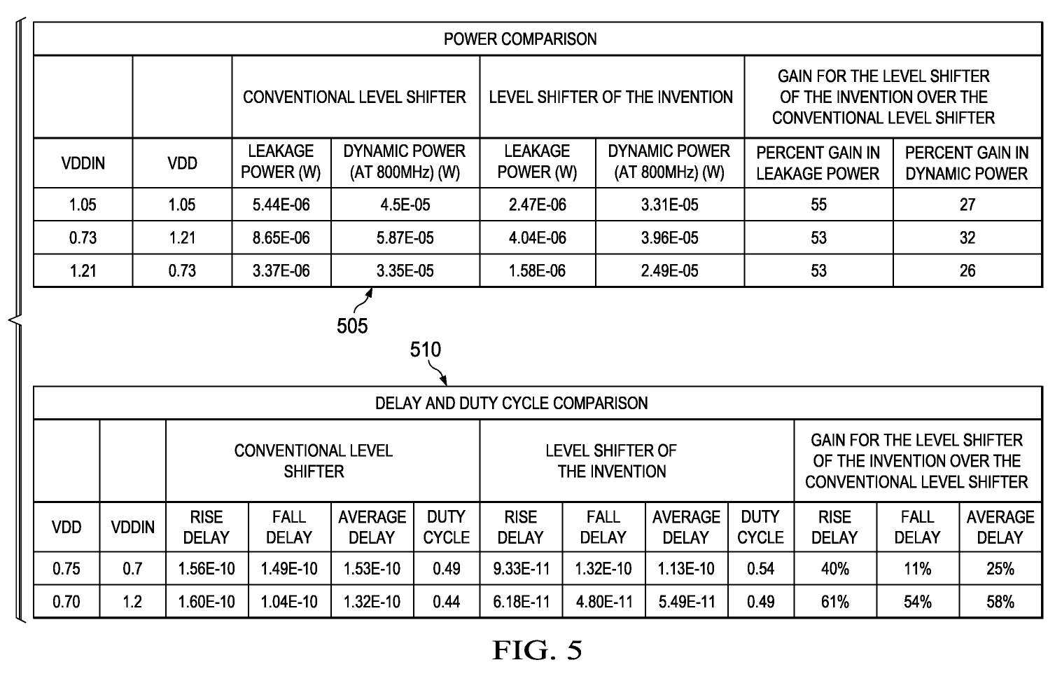

FIG. 5 illustrates the power and duty cycle comparison between the conventional level shifter 100 and the level shifter of FIG. 3. Table 505 illustrates the power comparison and table 510 illustrates the delay and duty cycle comparison. Experiment to measure leakage power and dynamic power were conducted at 105 C temperature. Table 505 illustrates that the level shifter 300 achieves a 55% gain in leakage power and 27% gain in dynamic power compared to the conventional circuit 100.

In table 510, the rise delay, fall delay, average delay and the duty cycle periods are illustrated. The rise delay, fall delay, average delay are expressed in the unit of seconds. The voltage levels of the input signal, VDDIN, and the voltage level of the output signal, VDD, are expressed in the unit of volts. As clear from the table 510, for voltage up-shifting, there is a gain in average delay of up to 25% (0.7V->0.75V). For voltage down-shifting the gain in average delay is 58% (1.2V->0.7V). The level shifter 300 also achieves a reduced duty cycle variation between 49% and 56% as compared to a duty cycle variation of 44%-55% in the conventional circuit 100.

In the foregoing discussion, the terms “connected” means at least either a direct electrical connection between the devices connected or an indirect connection through one or more passive intermediary devices. The term “circuit” means at least either a single component or a multiplicity of passive components, that are connected together to provide a desired function. The term “signal” means at least one current, voltage, charge, data, or other signal.

The forgoing description sets forth numerous specific details to convey a thorough understanding of the invention. However, it will be apparent to one skilled in the art that the invention may be practiced without these specific details. Well-known features are sometimes not described in detail in order to avoid obscuring the invention. Other variations and embodiments are possible in light of above teachings, and it is thus intended that the scope of invention not be limited by this Detailed Description, but only by the following Claims.

1. A level shifter comprising:
an input stage comprising a first circuit coupled to a second circuit, the first circuit comprising a first pull up transistor coupled to a first pull down transistor, the first pull down transistor receiving an input signal, the second circuit comprising a second pull up transistor coupled to a second pull down transistor, an output of the input stage coupled to a first node in the first circuit;
an inverter receiving the input signal, an output of the inverter and the gate of the second pull down transistor coupled to a second node; and
an output stage generating an output signal, the output stage comprising a first transistor coupled to the first node and a second transistor coupled to the second node.

2. The level shifter of claim 1, wherein:
the first node and the first transistor comprise a rise path of the level shifter and the first node drives the first transistor; and
the second node and the second transistor comprise a fall path of the level shifter and the second node drives the second transistor.

3. The level shifter of claim 1, wherein the first pull up transistor and the second pull up transistor are cross coupled to each other, and wherein the input stage receives a power supply voltage and the inverter receives another power supply voltage.

4. The level shifter of claim 2, wherein the first node comprises a common junction between the first pull up transistor and the first pull down transistor.

5. The level shifter of claim 3, wherein the output of the input stage is derived from the first node.

6. The level shifter of claim 2, wherein the rise path and the fall path comprises two separate paths.

7. The level shifter of claim 6, wherein a delay of rise path and a delay of the fall path are close to each other thereby maintaining a duty cycle distortion.

8. The level shifter of claim 1, wherein the output stage eliminates a need for an inverter at the output stage.

9. The level shifter of claim 8, wherein the first transistor and second transistor of the output stage are sized to match output drive requirements in the absence of the inverter at the output stage; and wherein the first transistor comprises a PMOS transistor and the second transistor comprises an NMOS transistor.

10. The level shifter of claim 9, wherein gates of the first transistor and the second transistor are coupled to the first node and the second node respectively.

11. The level shifter of claim 1, whereby reducing power consumption, leakage current and improving area efficiency.

12. A level shifter comprising:
an input stage coupled to an input node, the input node receiving an input signal, the input stage comprising:
a first circuit coupled to a second circuit, the first circuit comprising a first pull down transistor, a first pull up transistor and a first PMOS transistor sequentially coupled to each other, wherein gates of the first pull down transistor and the first PMOS transistor are coupled to the input node, and wherein an output of the input stage is coupled to a first node between the first pull up transistor and the first pull down transistor; and
the second circuit comprising a second pull down transistor, a second pull up transistor and a second PMOS transistor sequentially coupled to each other, an output of the input stage coupled to the first node in the first circuit, and the first pull up transistor and second pull up transistor being cross coupled to each other;
an inverter receiving the input signal, an output of the inverter and the gates of the second pull down transistor and second PMOS transistor coupled to a second node; and
an output stage generating an output signal, the output stage comprising a first transistor coupled to the first node and a second transistor coupled to the second node.

13. The level shifter of claim 12, wherein:
sources of the first PMOS transistor and the second PMOS transistor receives a power supply voltage; and
the first PMOS transistor selectively blocks the power supply voltage to the first circuit of the input stage and the second PMOS transistor selectively blocks the power supply voltage to the second circuit of the input stage.

14-16. (canceled)
